(19) United States
(12) Patent Application Publication
(10) Pub. No.: US 2017/0110587 A1
(43) Pub. Date: Apr. 20, 2017

(54) ARRAY SUBSTRATE AND MANUFACTURING METHOD THEREOF, DISPLAY PANEL, DISPLAY DEVICE

(71) Applicants: BOE TECHNOLOGY GROUP CO., LTD., Beijing (CN); BEIJING BOE DISPLAY TECHNOLOGY CO., LTD., Beijing (CN)

(72) Inventors: Yao LIU, Beijing (CN); Jinchao BAI, Beijing (CN); Xiangqian DING, Beijing (CN); Huibin GUO, Beijing (CN); Xi CHEN, Beijing (CN); Qihui WANG, Beijing (CN); Jing WANG, Beijing (CN)

(21) Appl. No.: 15/254,114

(22) Filed: Sep. 1, 2016

(30) Foreign Application Priority Data
Oct. 19, 2015 (CN) 201510679279.5

(51) Int. Cl. H01L 29/786; H01L 21/28; G02F 1/1343; G02F 1/1362; G02F 1/1368; H01L 27/12; G02F 1/1333

(52) U.S. Cl. CPC H01L 29/78606; H01L 27/1222; H01L 27/124; H01L 29/78678; H01L 29/78696; H01L 29/78618; H01L 27/1262; H01L 21/28247; G02F 1/133345; G02F 1/136227; G02F 1/1368; G02F 1/134363; G02F 2201/123; G02F 2201/50; G02F 2201/121; G02F 2202/104

(57) ABSTRACT

An array substrate and a manufacturing method thereof, a display panel, and a display device are provided. The array substrate includes a substrate; a source-drain metallic layer and a first passivation metallic protective layer formed in sequence on the substrate, the source-drain metallic layer including a source electrode and a drain electrode not contacted with each other; a conductive protection layer formed on the substrate on which the first passivation metallic protection layer has been formed; and a pixel electrode formed on the substrate on which the conductive protection layer has been formed, the pixel electrode contacting the conductive protection layer.

### TECHNICAL FIELD

Embodiments of the present disclosure relate to an array substrate and a manufacturing method thereof, a display panel, and a display device.

### BACKGROUND

ADvanced Super Dimension Switch (ADS) display mode is such a display mode that it achieves image display by utilizing a horizontal electric field generated by electrodes located in a same plane to deflect liquid crystals. The ADS display mode has advantageous, such as wide viewing angle, high resolution and low power consumption, and is widely applied in products, such as mobile phone, notebook computer and television.

### SUMMARY

Embodiments of the present disclosure provide an array substrate and a manufacturing method thereof, a display panel, and a display device. According to at least one embodiment of the present disclosure, an array substrate is provided, including a substrate; a source-drain metallic layer and a first passivation metallic protection layer formed in sequence on the substrate, the source-drain metallic layer comprising a source electrode and a drain electrode not contacted with each other; a conductive protection layer formed on the substrate on which the first passivation metallic protection layer has been formed; and a pixel electrode formed on the substrate on which the conductive protection layer has been formed, the pixel electrode being contacted with the conductive protection layer.

In an example, the conductive protection layer is obtained by performing an annealing process at a temperature of 250˜270° C.

In an example, the conductive protection layer is a polycrystalline silicon-indium tin oxide (p-ITO) protection layer.

In an example, the array substrate further includes a passivation layer formed on the substrate on which the conductive protection layer has been formed, a via hole being formed in the passivation layer, and the pixel electrode being contacted with the conductive protection layer through the via hole.

In an example, the array substrate further includes a common electrode, a gate electrode, a gate insulating layer and an active layer formed in sequence on the substrate, the source-drain metallic layer and the first passivation metallic protection layer being formed on the active layer.

In an example, the array substrate further includes a second passivation metallic protection layer formed on the substrate on which the active layer has been formed.

In an example, both of the first passivation metallic protection layer and the second passivation metallic protection layer are made of molybdenum.

According to at least one embodiment of the present disclosure, a manufacturing method of an array substrate is provided, the array substrate includes a substrate, and the manufacturing method of the array substrate includes: forming a source-drain metallic layer and a first passivation metallic protection layer in sequence on the substrate, the source-drain metallic layer including a source electrode and a drain electrode not contacted with each other; forming a conductive protection layer on the substrate on which the first passivation metallic protection layer has been formed; and forming a pixel electrode on the substrate on which the conductive protection layer has been formed, the pixel electrode being contacted with the conductive protection layer.

In an example, the conductive protection layer is a polycrystalline silicon-indium tin oxide (p-ITO) protection layer.

In an example, the manufacturing method further includes: forming an amorphous silicon-indium tin oxide (a-ITO) layer on the substrate on which the first passivation metallic protection layer has been formed; and performing a patterning process and an annealing process in sequence to the a-ITO layer to obtain the conductive protection layer.

In an example, the manufacturing method further includes: performing an annealing process to the a-ITO layer at a temperature of 250˜270° C.

In an example, the manufacturing method further includes: after forming the conductive protection layer on the substrate on which the first passivation metallic protection layer has been formed, forming a passivation layer on the substrate on which the conductive protection layer has been formed; forming a via hole in the passivation layer; and forming the pixel electrode on the substrate on which the passivation layer has been formed so that the pixel electrode being contacted with the conductive protection layer through the via hole.

In an example, the manufacturing method further includes: before forming a source-drain metallic layer and a first passivation metallic protection layer in sequence on the substrate, forming a common electrode, a gate electrode, a gate insulating layer and an active layer in sequence on the substrate; and forming the source-drain metallic layer and the first passivation metallic protection layer in sequence on the substrate on which the active layer has been formed.

In an example, the manufacturing method further includes: forming a second passivation metallic protection layer on the substrate on which the active layer has been formed; and forming the source-drain metallic layer and the first passivation metallic protection layer in sequence on the substrate on which the second passivation metallic protection layer has been formed.

In an example, both of the first passivation metallic protection layer and the second passivation metallic protection layer are made of molybdenum.

According to the embodiments of the present disclosure, a display panel is provided, including the array substrate.

According to the embodiments of the present disclosure, a display device is provided, including the array substrate.

### BRIEF DESCRIPTION OF THE DRAWINGS

Embodiments of the present disclosure will be illustrated in more details in connection with the drawings so as to enable those skilled in the art to understand the disclosure more clearly, wherein

FIG. 1 is a schematically structural diagram illustrating an array substrate;

FIG. 2 is a schematically structural diagram illustrating an array substrate provided by an embodiment of the present disclosure;

FIG. 3 is a schematically structural diagram illustrating an array substrate provided by another embodiment of the present disclosure;

FIG. 4 is a schematically structural diagram illustrating another array substrate provided by the embodiment as illustrated in FIG. 3;

FIG. 5 is a flow chart illustrating a manufacturing method of an array substrate provided by an embodiment of the present disclosure;

FIG. 6 is a flow chart illustrating a manufacturing method of an array substrate provided by another embodiment of the present disclosure;

FIG. 7 is a schematic diagram illustrating a structure with a common electrode formed on a substrate, as provided by the embodiment as illustrated in FIG. 6;

FIG. 8 is a schematic diagram illustrating a structure with a gate electrode formed on a substrate on which a common electrode has been formed, as provided by the embodiment as illustrated in FIG. 6;

FIG. 9 is a schematic diagram illustrating a structure with a gate insulating layer formed on a substrate on which a gate electrode has been formed, as provided by the embodiment as illustrated in FIG. 6;

FIG. 10 is a schematic diagram illustrating a structure with an active layer formed on a substrate on which a gate insulating layer has been formed, as provided by the embodiment as illustrated in FIG. 6;

FIG. 11 is a schematic diagram illustrating a structure with a second passivation metallic protection layer on a substrate on which an active layer has been formed, as provided by the embodiment as illustrated in FIG. 6;

FIG. 12 is a schematic diagram illustrating a structure with a source-drain metallic layer formed on a substrate on which a second passivation metallic protection layer has been formed, as provided by the embodiment as illustrated in FIG. 6;

FIG. 13 is a schematic diagram illustrating a structure with a first passivation metallic protection layer formed on a substrate on which a source-drain metallic layer has been formed, as provided by the embodiment as illustrated in FIG. 6;

FIG. 14 is a schematic diagram illustrating a structure with a conductive protection layer formed on a substrate on which a first passivation metallic protection layer has been formed, as provided by the embodiment as illustrated in FIG. 6;

FIG. 15 is a schematic diagram illustrating a structure with a conductive protection layer formed on a substrate on which a first passivation metallic protection layer has been formed, as provided by the embodiment as illustrated in FIG. 6;

FIG. 16 is a flow chart illustrating a process of forming a conductive protection layer on a substrate on which a first passivation metallic protection layer has been formed, as provided by the embodiment as illustrated in FIG. 6;

FIG. 17 is a schematic diagram illustrating a structure with a passivation layer formed on a substrate on which a conductive protection layer has been formed, as provided by the embodiment as illustrated in FIG. 6;

FIG. 18 is a schematic diagram illustrating a structure with a via hole formed in a passivation layer, as provided by the embodiment as illustrated in FIG. 6;

FIG. 19 is a schematic diagram illustrating a structure with a pixel electrode formed on a substrate on which a passivation layer has been formed, as provided by the embodiment as illustrated in FIG. 6.

### DETAILED DESCRIPTION

Embodiments of the present disclosure will be described in details in connection with the drawings related to the embodiments of the present disclosure. It is apparent that the described embodiments are just a part but not all of the embodiments of the present disclosure. Based on the described embodiments herein, an ordinary skill in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms, such as “first,” “second,” or the like, which are used in the description and the claims of the present application, are not intended to indicate any sequence, amount or importance, but for distinguishing various components. The terms, such as “comprise/comprising,” “include/including,” or the like are intended to specify that the elements or the objects stated before these terms encompass the elements or the objects and equivalents thereof listed after these terms, but not preclude other elements or objects. The terms, “on,” “under,” or the like are only used to indicate relative position relationship, and when the position of the object which is described is changed, the relative position relationship may be changed accordingly.

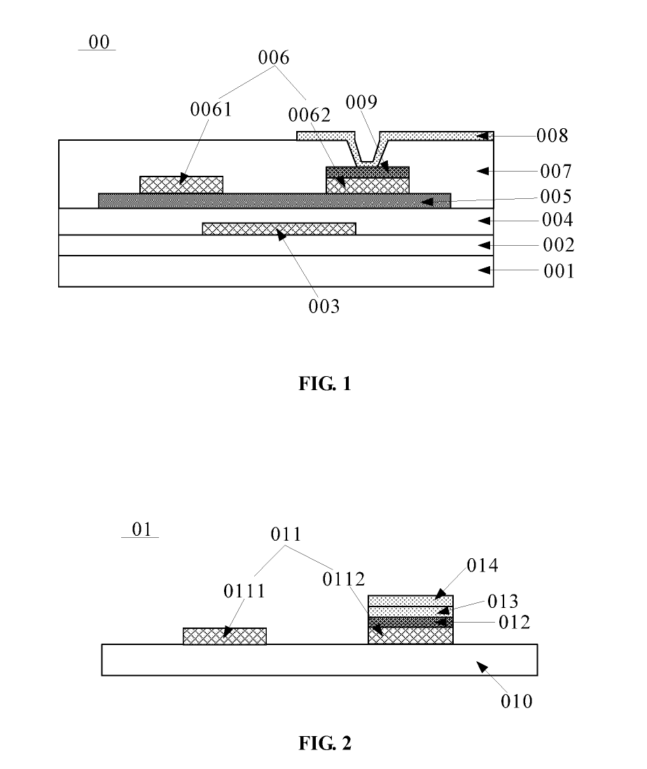

A display device includes an array substrate. For example, as shown in FIG. 1, a structure of an array substrate 00 is illustrated, the array substrate 00 can include a substrate 001 on which an Indium Tin Oxide (ITO), a common electrode 002, a gate electrode 003, a gate insulating layer 004, an active layer 005, a source-drain metallic layer 006, a passivation layer 007 and a ITO electrode 008 are formed in sequence. The source-drain metallic layer 006 includes a source electrode 0061 and a drain electrode 0062, a via hole is formed in the passivation layer 007, and the ITO electrode is contacted with the drain electrode 0062 through the via hole in the passivation layer 007. The drain electrode 0062 is usually made of Al; contacting between the ITO electrode 008 and the drain electrode 0062 is liable to cause an oxidation of the drain electrode 0062 and increase a resistance between the ITO electrode 008 and the drain electrode 0062, so that a transmission of signals is impacted. Consequently, as shown in FIG. 1, before forming the passivation layer 007, a layer of metal Mo (molybdenum) can be plated onto a surface of the drain electrode 0062 to prevent the ITO electrode 008 and the drain electrode 0062 from being directly contacted with each other, and to avoid oxidation of the drain electrode 0062.

However, the inventor found that relevant technologies involve problems as below: when forming the via hole in the passivation layer by using an etching process, the metal Mo that is located beneath the passivation layer, at a position corresponding to the via hole, may be etched off in case an over-etching is happened; consequently, the ITO electrode will still be directly contacted with the drain electrode, with a relatively larger resistance between the ITO electrode and the drain electrode.

Referring to FIG. 2 illustrating a structure of an array substrate 01 provided by an embodiment of the present disclosure. As illustrated in FIG. 2, the array substrate 01 includes a substrate 010. The substrate 010 can be a transparent substrate, for example, a substrate made of a non-metallic, light-transmittance material with certain strength, such as glass, quartz and transparent resin.

On the substrate 010, a source-drain metallic layer 011 and a first passivation metallic protection layer 012 are formed in sequence. The source-drain metallic layer 011 includes a source electrode 0111 and a drain electrode 0112 not contacted with each other; a conductive protection layer 013 is formed on the substrate 010 on which the first passivation metallic protection layer 012 has been formed; and a pixel electrode 014 is formed on the substrate 101 on which the conductive protection layer 013 has been formed, the pixel electrode 014 is contacted with the conductive protection layer 013.

In the array substrate provided by the present embodiment, a conductive protection layer is formed on a first passivation metallic protection layer to prevent the first passivation metallic protection layer from being etched off, and to avoid a direct contact between a pixel electrode and a drain electrode. In this way, a problem of a relatively large resistance between the pixel electrode and the drain electrode is solved, which allows a proper resistance between the pixel electrode and the drain electrode.

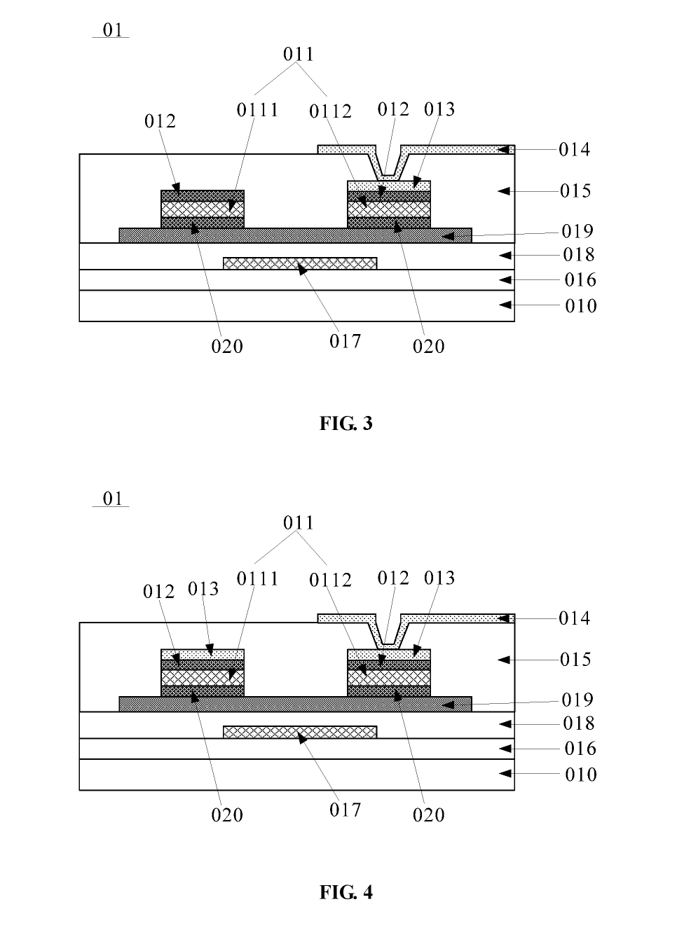

Referring to FIG. 3 illustrating a schematic structure of an array substrate 01 provided by another embodiment of the present disclosure. As illustrated in FIG. 3, the array substrate 01 includes a substrate 010 which can be a transparent substrate, for example, a substrate made of a non-metallic, light-transmittance material with certain strength, such as glass, quartz and transparent resin.

On the substrate 010, a source-drain metallic layer 011 and a first passivation metallic protection layer 012 are formed in sequence; the source-drain metallic layer 101 includes a source electrode 0111 and a drain electrode 0112 not contacted with each other. The source-drain metallic layer 011 and the first passivation metallic protection layer 012 can be formed on the substrate 010 by using two patterning processes, and each patterning process includes coating a photoresist, and exposing, developing, etching and peeling off the photoresist. For example, forming of the source-drain metallic layer 011 can include: forming a metallic layer on the substrate 010 by a process of coating, magnetron sputtering, thermal evaporation, or plasma enhanced chemical vapor deposition (PECVD); then, processing the metallic layer by a patterning process to obtain the source-drain metallic layer 011. As for the process of forming the first passivation metallic protection layer 012, reference can be made to that of the source-drain metallic layer 011 without repeating herein.

A conductive protection layer 013 is formed on the substrate 010 on which the first passivation metallic protection layer 012 has been formed. The conductive protection layer 013 can be formed by a patterning process and an annealing process. The patterning process includes: coating a photoresist; and exposing, developing, etching and peeling off the photoresist. An annealing temperature used in the annealing process can be 250˜270° C. For example, the annealing temperature is about 270° C. The conductive protection layer 013 can be a polycrystalline silicon-ITO (p-ITO) protection layer. In most cases, the amorphous silicon-ITO (a-ITO) is liable to be etched, but can be converted into the p-ITO by performing an annealing process thereto. The p-ITO is impossible to be etched off by using an etching process without aqua regia. Correspondingly, in an embodiment of the present disclosure, it is possible to firstly form an a-ITO layer on the substrate 010 on which the first passivation metallic protection layer 012 has been formed, by using a-ITO as the material through a process of coating, magnetron sputtering, thermal evaporation, or plasma enhanced chemical vapor deposition (PECVD), then, to process the a-ITO layer by a patterning process, then to process the patterned a-ITO layer by using an annealing process at a temperature of 250˜270° C. so as to obtain the conductive protection layer 013. It should be explained that the embodiment of the present disclosure is described with reference to the case where the conductive protection layer 013 is formed by using a-ITO as the material through a patterning process and an annealing process by way of example, however, embodiments of the present disclosure are not limited thereto, for example, the conductive protection layer 013 can also be formed by using other materials.

In should be explained that, in the embodiment of the present disclosure, as shown in FIG. 3, the conductive protection layer 013 can be located in an area on the first passivation metallic protection layer 012 corresponding to the drain electrode 0112; or, as illustrated in FIG. 4, the conductive protection layer 013 can also be located in an area on the first passivation metallic protection layer 012 corresponding to the source electrode 0111 and the drain electrode 0112, however, embodiments of the present disclosure are not limited thereto.

Referring to FIG. 3 or FIG. 4, a pixel electrode 014 is formed on the substrate 101 on which the conductive protection layer 013 has been formed, and the pixel electrode 014 is contacted with the conductive protection layer 013. The pixel electrode can be formed by using a metallic material. For example, it is possible to firstly form a metallic layer on the substrate 010 on which the conductive protection layer 013 has been formed, and then to process the metallic layer by using a patterning process to obtain the pixel electrode 014. The patterning process includes: coating a photoresist; and exposing, developing, etching and peeling off the photoresist.

Referring to FIG. 3 or FIG. 4 again, for example, a passivation layer 015 is formed on the substrate 010 on which the conductive protection layer 013 has been formed, a via hole (not illustrated in FIG. 3 or FIG. 4) is formed in the passivation layer 015, and the pixel electrode 014 is contacted with the conductive protection layer 013 through the via hole. A process of coating, magnetron sputtering, thermal evaporation, or plasma enhanced chemical vapor deposition (PECVD) can be used to form the passivation layer 015 on the substrate 010 on which the conductive protection layer 013 has been formed. For example, sputtering a layer of silicide with a certain thickness on the substrate 101 on which the conductive protection layer 013 has been formed to form the passivation layer 015. The passivaton layer 015 can be selected from a group consisting of oxide, nitride and oxynitride, and corresponding reactant gas can be a mixed gas of SiH₄, NH₃ and N₂ or a mixed gas of SiH₂Cl₂, NH₃ and N₂, however, embodiments of the present disclosure are not limited thereto. It should be explained that, in applications, when the passivation layer 015 includes a pattern, it can be processed by using a patterning process which will not be repeated herein in detail.

Referring to FIG. 3 or FIG. 4 again, for example, a common electrode 016, a gate electrode 017, a gate insulating layer 018 and an active layer 019 are formed in sequence on the substrate 010; and a source-drain metallic layer 011 and a first passivation metallic protection layer 012 are formed in sequence on the substrate 010 on which the active layer 019 has been formed. The common electrode 016, the gate electrode 017, the gate insulating layer 018 and the active layer 019 cam be formed on the substrate 010 by four patterning processes, each patterning process includes coating a photoresist, and exposing, developing, etching and peeling off the photoresist. It should be explained that an insulating layer is disposed between the common electrode 016 and the gate electrode 017 to insulate the common electrode 016 and the gate electrode 017 from one another, which is not repeated herein in detail.

Referring to FIG. 3 or FIG. 4 again, for example, a second passivation metallic protection layer 020 is formed on the substrate 010 on which the active layer 019 has been formed; a source-drain metallic layer 011 and a first passivation metallic protection layer 012 are formed in sequence on the substrate 010 on which the second passivation metallic protection layer 020 has been formed. Both of the first passivation metallic protection layer 012 and the second passivation metallic protection layer 020 can made of molybdenum. By disposing the second passivation metallic protection layer 020, a cross contamination between the source-drain metallic layer 011 and the active layer 019 can be avoided. As for the process of forming the second passivation metallic protection layer 020, reference can be made to that of the first passivation metallic protection layer 012, which is not repeated herein in detail.

It should be explained that the embodiment of the present disclosure is described with reference to the case where the first and the second passivation metallic protection layers 012, 020 are made of same material, and the materials of forming the first and the second passivation metallic protection layers 012, 020 both are molybdenum by way of example, however, embodiments of the present disclosure are not limited thereto. For example, the material of forming the first passivation metallic protection layer 012 and the material of forming the second passivation metallic protection layer 020 can be different and are not limited to metal molybdenum.

In the array substrate provided by the embodiment of the present disclosure, a conductive protection layer is formed on a first passivation metallic protection layer to prevent the first passivation metallic protection layer from being etched, and hence to avoid a direct contact between a pixel electrode and a drain electrode. In this way, the problem of a relatively large resistance between the pixel electrode and the drain electrode is solved.

The manufacturing method and manufacture principle of the array substrate provided by the embodiment of the present disclosure are described by referring to the following embodiments.

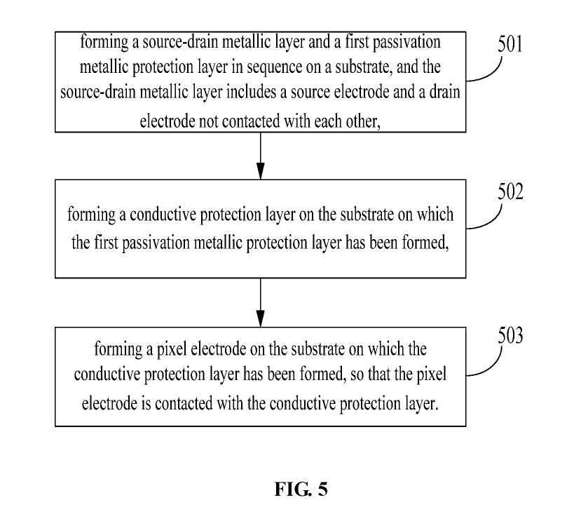

Referring to FIG. 5 illustrating a flow chart of a manufacturing method of an array substrate provided by an embodiment of the present disclosure, the manufacturing method can be applicable for manufacturing the array substrates as illustrated in any of FIGS. 2-4. The array substrate can include a substrate which can be a transparent substrate. For example, the substrate can be a substrate made of a non-metallic, light-transmittance material with certain strength, such as glass, quartz and transparent resin. Referring to FIG. 5 again, the manufacturing method of the array substrate can include steps as below.

Step S501, forming a source-drain metallic layer and a first passivation metallic protection layer in sequence on a substrate, the source-drain metallic layer includes a source electrode and a drain electrode not contacted with each other.

Step S502, forming a conductive protection layer on the substrate on which the first passivation metallic protection layer has been formed.

Step S503, forming a pixel electrode on the substrate on which the conductive protection layer has been formed, so that the pixel electrode is contacted with the conductive protection layer.

In the manufacturing method of an array substrate provided by the present embodiment, a conductive protection layer is formed on a first passivation protection layer to prevent the first passivation protection layer from being etched off, and hence to avoid a direct contact between a pixel electrode and a drain electrode. In this way, the problem of a relatively large resistance between the pixel electrode and the drain electrode is solved.

For example, before the step S501, the manufacturing method of an array substrate further includes: forming a common electrode, a gate electrode, a gate insulating layer and an active layer in sequence on the substrate; correspondingly, the step S501 can include: forming a source-drain metallic layer and a first passivation metallic protection layer in sequence on the substrate on which the active layer has been formed.

For example, the manufacturing method of an array substrate further includes: before forming the source-drain metallic layer and the first passivation metallic protection layer in sequence on the substrate on which the active layer has been formed, firstly forming a second passivation metallic protection layer on the substrate on which the active layer has been formed.

In other words, forming the source-drain metallic layer and the first passivation metallic protection layer in sequence on the substrate on which the second passivation metallic protection layer has been formed.

For example, both of the first passivation metallic protection layer and the second passivation metallic protection layer are formed by molybdenum.

For example, the conductive protection layer is a p-ITO protection layer.

The step S502 can include: forming an a-ITO layer on the substrate on which the first passivation metallic protection layer has been formed; processing the a-ITO layer by using a patterning process and an annealing process in sequence to obtain the conductive protection layer.

For example, processing the a-ITO layer by using an annealing process includes: processing the a-ITO layer by using an annealing process at a temperature of 250˜270° C.

For example, the manufacturing method of an array substrate further includes: after the step S502, forming a passivation layer on the substrate on which the conductive protection layer has been formed; and forming a via hole in the passivation layer; Correspondingly, the step S503 can include: forming a pixel electrode on the substrate on which the passivation layer has been formed so that the pixel electrode is contacted with the conductive protection layer through the via hole.

The above-mentioned examples can be combined in any ways so as to constitute illustrative embodiments of the present disclosure, which are not repeated in details herein.

In the manufacturing method of an array substrate provided by the present embodiments, a conductive protection layer is formed on a first passivation protection layer to prevent the first passivation protection layer from being etched off, and hence to avoid a direct contact between a pixel electrode and a drain electrode; in this way, the problem of a relatively large resistance between the pixel electrode and the drain electrode is solved.

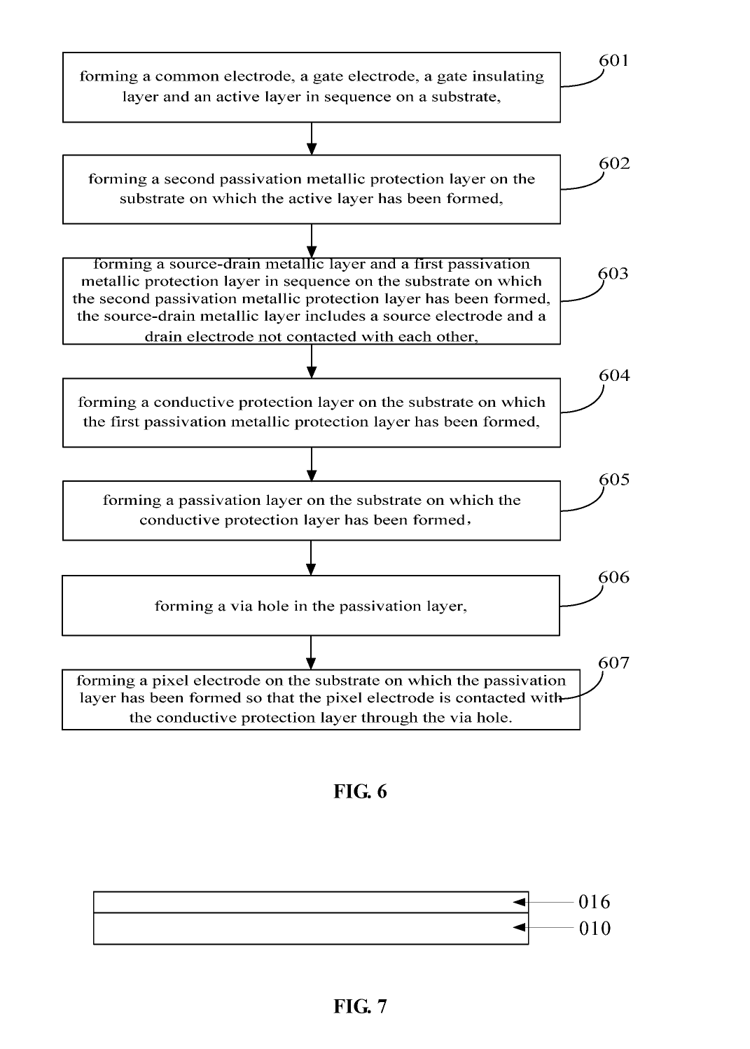

Referring to FIG. 6, which illustrates a flow chart of a manufacturing method of an array substrate provided by another embodiment of the present disclosure, the manufacturing method is applicable for manufacturing the array substrate 01 as shown in any of FIGS. 2-4. The array substrate 01 can include a substrate 010 which can be a transparent substrate, for example, a substrate made of a non-metallic, light-transmittance material with certain strength, such as glass, quartz and transparent resin. Referring to FIG. 6 again, the manufacturing method of the array substrate can include steps as below.

Step S601, forming a common electrode, a gate electrode, a gate insulating layer and an active layer in sequence on a substrate.

Referring to FIG. 7, which illustrates a structure with a common electrode 016 formed on a substrate 010 as provided by the embodiment as illustrated in FIG. 6. The common electrode 016 can be formed by using a metallic material, for example, the common electrode 016 can be formed by using ITO, however, embodiments of the present disclosure are not limited thereto.

For example, depositing a layer of ITO material on the substrate 101 by using a process of coating, magnetron sputtering, thermal evaporation, or plasma enhanced chemical vapor deposition (PECVD) to form an ITO layer; then processing the ITO layer by using a patterning process to obtain the common electrode 016. For example, processing the ITO layer by using a patterning process to obtain the common electrode 016 can include: coating a layer of photoresist with a certain thickness on the ITO layer; exposing the photoresist by using a mask to form a fully-exposed area and a non-exposed area of the photoresist; then performing a developing process to completely remove the photoresist in the fully-exposed area and fully remain the photoresist in the non-exposed area; etching an area on the ITO layer corresponding to the fully-exposed area by using an etching process; and then peeling off the photoresist in the non-exposed area so that an area on the ITO layer corresponding to the non-exposed area forms the common electrode 016. It should be explained that the embodiment of the present disclosure is described with reference to the case where the common electrode 016 is formed by using positive photoresist, however, embodiments of the disclosure are not limited thereto, for example, it is also possible to form the common electrode 016 by using negative photoresist.

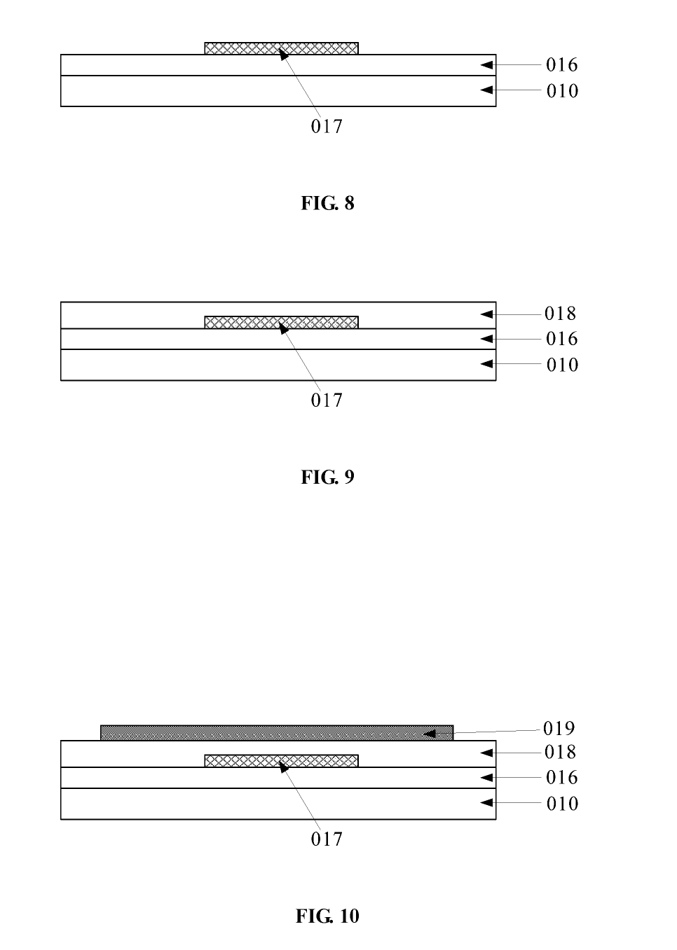

Referring to FIG. 8, which shows a structure with a gate electrode 017 formed on a substrate 010 on which a common electrode 016 has been formed, as provided by the embodiment as illustrated in FIG. 6. The gate electrode 017 can be formed by using a metallic material.

For example, depositing a layer of metallic material on the substrate 010 on which the common electrode 016 has been formed by using a process of coating, magnetron sputtering, thermal evaporation, or plasma enhanced chemical vapor deposition (PECVD) to form a metallic layer; then processing the metallic layer by using a patterning process to obtain the gate electrode 017. For example, processing the metallic layer by using the patterning process to obtain the gate electrode 017 can include: coating a layer of photoresist at a certain thickness on the metallic layer; exposing the photoresist by using a mask to form a fully-exposed area and a non-exposed area of the photoresist; then performing a developing process to completely remove the photoresist in the fully-exposed area and fully remain the photoresist in the non-exposed area; etching an area on the metallic layer corresponding to the fully-exposed area by using an etching process; and then peeling off the photoresist in the non-exposed area so that an area on the metallic layer corresponding to the non-exposed area forms the gate electrode 017. It should be explained that the embodiment of the present disclosure is described with reference to the case where the gate electrode 017 is formed by using positive photoresist, however, embodiments of the present disclosure are not limited thereto, for example, it is also possible to form the gate electrode 017 by using negative photoresist.

It should be explained that an insulating layer is disposed between the common electrode 016 and the gate electrode 017 to insulate the common electrode and the gate electrode 017 from one another, which is not repeated herein in detail.

Referring to FIG. 9, which shows a structure with a gate insulating layer 018 formed on a substrate 010 on which a gate electrode 017 has been formed, as provided by the embodiment as illustrated in FIG. 6. The gate insulating layer 018 can be formed by an organic resin material, and a thickness of the gate insulating layer 018 can be designed according to requirements.

For example, depositing a layer of organic resin material with a certain thickness on the substrate 010 on which the gate electrode 017 has been formed, by a process of coating, magnetron sputtering, thermal evaporation, or plasma enhanced chemical vapor deposition (PECVD) to form the gate insulating layer 018. For example, when the gate insulating layer 018 includes a pattern, it can be obtained by using a patterning process, however, embodiments of the present disclosure are not limited thereto.

Referring to FIG. 10, which shows a structure with an active layer 019 on a substrate 010 on which a gate insulating layer 018 has been formed, as provided by the embodiment as illustrated in FIG. 6. The active layer 019 can be formed by using polycrystalline silicon, and a thickness of the active layer 019 can be designed according to requirements, however, embodiments of the present disclosure are not limited thereto.

For example, depositing a polycrystalline silicon thin film on the substrate 010 on which the gate insulating layer 018 has been formed by using a process of coating, magnetron sputtering, thermal evaporation, or plasma enhanced chemical vapor deposition (PECVD); then processing the polycrystalline silicon thin film by using a patterning process to obtain the active layer 019. For example, processing the polycrystalline silicon thin film by using the patterning process to obtain the active layer 019 can include: coating a layer of photoresist with a certain thickness on the polycrystalline silicon thin film; exposing the photoresist by using a mask to form a fully-exposed area and a non-exposed area of the photoresist; then performing a developing process to completely remove the photoresist in the fully-exposed area and fully remain the photoresist in the non-exposed area; etching an area on the polycrystalline silicon thin film corresponding to the fully-exposed area by using an etching process; and then peeling off the photoresist in the non-exposed area so that an area on the polycrystalline silicon thin film corresponding to the non-exposed area forms the active layer 019. It should be explained that the embodiment of the present disclosure is described with reference to the case where the active layer 019 is formed by using positive photoresist, however, embodiments of the present disclosure are not limited thereto, for example, it is also possible to form the active layer 019 by using negative photoresist.

Step S602, forming a second passivation metallic protection layer on the substrate on which the active layer has been formed.

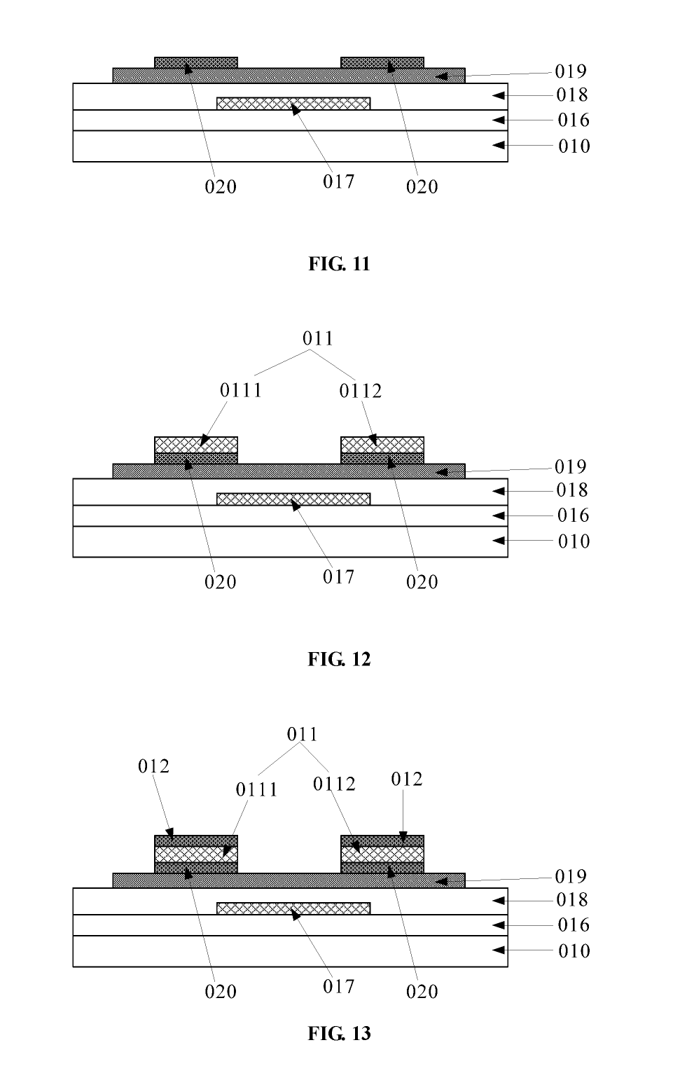

Referring to FIG. 11, which illustrates a structure with a second passivation metallic protection layer 020 on a substrate 010 on which an active layer 019 has been formed, as provided by the embodiment as illustrated in FIG. 6. The second passivation metallic protection layer 020 can be formed of metallic molybdenum, however, embodiments of the present disclosure are not limited thereto. By disposing the second passivation metallic protection layer 020, a cross contamination between the active layer 019 and a later formed source-drain metallic layer 011 can be avoided.

For example, depositing a metallic molybdenum layer on the substrate 010 on which the active layer 019 has been formed by using a process of coating, magnetron sputtering, thermal evaporation, or plasma enhanced chemical vapor deposition (PECVD); then processing the metallic molybdenum layer by using a patterning process to obtain the second passivation metallic protection layer 020. For example, processing the metallic molybdenum layer by using a patterning process to obtain the second passivation metallic protection layer 020 can include: coating a layer of photoresist with a certain thickness on the metallic molybdenum layer; exposing the photoresist by using a mask to form a fully-exposed area and a non-exposed area of the photoresist; then performing a developing process to completely remove the photoresist in the fully-exposed area and fully remain the photoresist in the non-exposed area; etching an area on the metallic molybdenum layer corresponding to the fully-exposed area by using an etching process; and then peeling off the photoresist in the non-exposed area so that an area on the metallic molybdenum layer corresponding to the non-exposed area forms the second passivation metallic protection layer 020. It should be explained that the embodiment of the present disclosure is described with reference to the case where the second passivation metallic protection layer 020 is formed by using positive photoresist, however, embodiments of the present disclosure are not limited thereto, for example, it is also possible to form the second passivation metallic protection layer 020 by using negative photoresist.

Step S603, forming a source-drain metallic layer and a first passivation metallic protection layer in sequence on the substrate on which the second passivation metallic protection layer has been formed, the source-drain metallic layer includes a source electrode and a drain electrode not contacted with each other.

Referring to FIG. 12, which shows a structure with a source-drain metallic layer 011 formed on a substrate 010 on which a second passivation metallic protection layer 020 has been formed, as provided by the embodiment as illustrated in FIG. 6. The source-drain metallic layer 011 can be formed by using a metallic material, such as aluminum, however, embodiments of the present disclosure are not limited thereto.

For example, depositing a metallic aluminum layer on the substrate 010 on which the second passivation metallic protection layer 020 has been formed by using a process of coating, magnetron sputtering, thermal evaporation, or plasma enhanced chemical vapor deposition (PECVD); then processing the metallic aluminum layer by using a patterning process to obtain the source-drain metallic layer 011. For example, processing the metallic aluminum layer by using the patterning process to obtain the source-drain metallic layer 011 can include: coating a layer of photoresist with a certain thickness on the metallic aluminum layer; exposing the photoresist by using a mask to form a fully-exposed area and a non-exposed area of the photoresist; then performing a developing process to completely remove the photoresist in the fully-exposed area and fully remain the photoresist in the non-exposed area; etching an area on the metallic aluminum layer corresponding to the fully-exposed area by using an etching process; and then peeling off the photoresist in the non-exposed area so that an area on the metallic aluminum layer corresponding to the non-exposed area forms the source-drain metallic layer 011. Etching the area on the metallic aluminum layer corresponding to the fully-exposed area can be performed by using a wet etching process, as illustrated in FIG. 12, the source-drain metallic layer 011 includes a source electrode 0111 and a drain electrode 0112 not contacted with each other, and both of the source electrode 0111 and the drain electrode 0112 are located on the second passivation metallic protection layer 020.

Referring to FIG. 13 which illustrates a structure with a first passivation metallic protection layer 012 formed on a substrate 010 on which a source-drain metallic layer 011 has been formed, as provided by the embodiment as illustrated in FIG. 6. The first passivation metallic protection layer 012 can be formed of metal molybdenum, however, embodiments of the present disclosure are not limited thereto. Disposing the first passivation metallic protection layer 012 can prevent a pixel electrode later formed on the first passivation metallic protection layer 012 from oxidizing the drain electrode 0112. The process of forming the first passivation metallic protection layer 012 is same as or similar to the process of forming the second passivation metallic protection layer 020 in the step S602, which is not repeated herein in details.

It should be explained that the embodiment of the present disclosure is described with reference to the case where the first and the second passivation metallic protection layers 012, 020 are made of same material, and both of the first and the second passivation metallic protection layers 012, 020 are made of molybdenum by way of example, however, embodiments of the present disclosure are not limited therefore, for example, the material of forming the first passivation metallic protection layer 012 and the material of forming the second passivation metallic protection layer 020 can be different and are not limited to metal molybdenum.

Step S604, forming a conductive protection layer on the substrate on which the first passivation metallic protection layer has been formed.

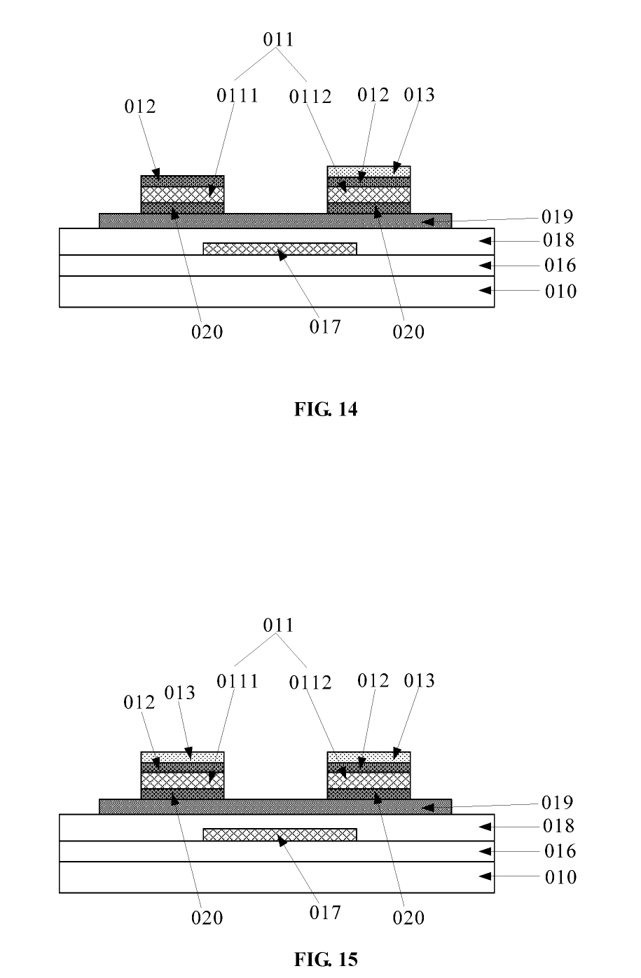

Referring to FIG. 14, which illustrates a structure with a conductive protection layer 013 formed on a substrate 010 on which a first passivation metallic protection layer 012 has been formed, as provided by the embodiment as illustrated in FIG. 6. As illustrated in FIG. 14, the conductive protection layer 013 is located in an area on the first passivation metallic protection layer 012 corresponding to the drain electrode 0112.

Referring to FIG. 15, which illustrates a structure with a conductive protection layer 013 formed on a substrate 010 on which a first passivation metallic protection layer 012 has been formed, as provided by the embodiment as illustrated in FIG. 6. As illustrated in FIG. 15, the conductive protection layer 013 is located in an area on the first passivation metallic protection layer 012 corresponding to the source electrode 0111 and the drain electrode 0112. In the embodiment of the present disclosure, the conductive protection layer 013 can be formed by using a metallic material; for example, the metallic material can be no.

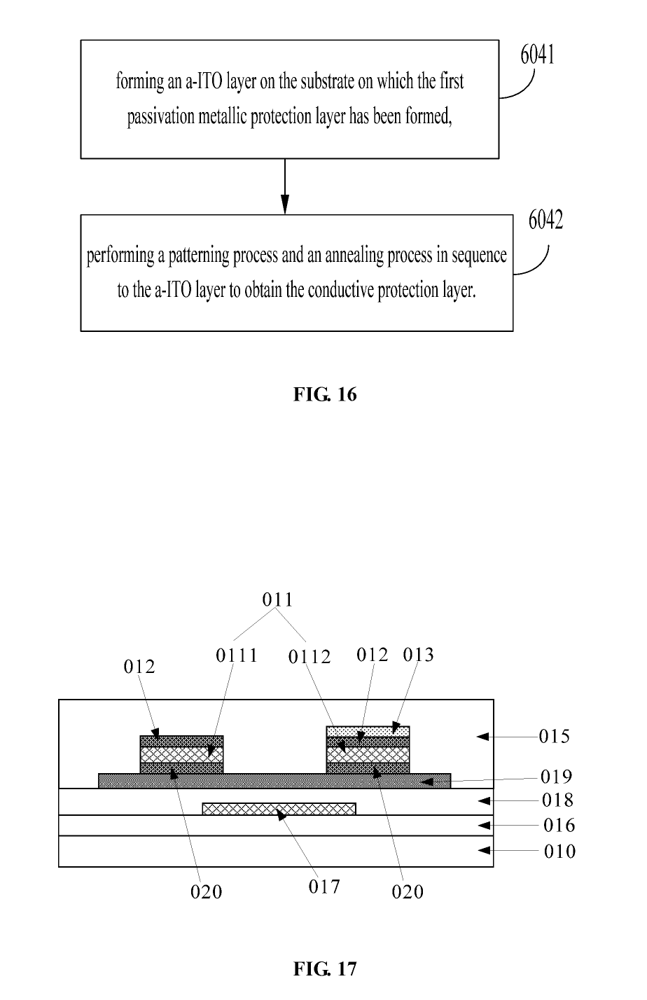

Referring to FIG. 16, which illustrates a process of forming a conductive protection layer 013 on a substrate 010 on which a first passivation metallic protection layer 012 has been formed, as provided by the embodiment as illustrated in FIG. 6. As illustrated in FIG. 16, the flow chart can include steps as below.

Step S6041, forming an a-ITO layer on the substrate on which the first passivation metallic protection layer has been formed.

For example, depositing a layer of a-ITO with a certain thickness on the substrate 010 on which the first passivation metallic protection layer 012 has been formed, by using a-ITO as the material through a process of coating, magnetron sputtering, thermal evaporation, or plasma enhanced chemical vapor deposition (PECVD).

Step S6042, performing a patterning process and an annealing process in sequence to the a-ITO layer to obtain the conductive protection layer.

The pattering process includes: coating a photoresist; and exposing, developing, etching and peeling off the photoresist. An annealing temperature used in the annealing process can be 250˜270° C. For example, the annealing temperature is about 270° C. The conductive protection layer 013 can be a p-ITO protection layer. In most cases, the a-ITO is liable to be etched, but can be converted into p-ITO by performing an annealing process thereto, the p-ITO is impossible to be etched by methods other than an etching process using aqua regia.

For example, coating a layer of photoresist with a certain thickness on the a-ITO layer; exposing the photoresist by using a mask to form a fully-exposed area and a non-exposed area of the photoresist; then performing a developing process to completely remove the photoresist in the fully-exposed area and fully remain the photoresist in the non-exposed area; etching an area on the a-ITO layer corresponding to the fully-exposed area by using an etching process; then peeling off the photoresist in the non-exposed area and processing the a-ITO layer by using an annealing process at a temperature of 250˜270° C. so that the a-ITO is converted into p-ITO to obtain the conductive protection layer 013. It should be explained that the embodiment of the present disclosure is described with reference to the case where the conductive protection layer is formed by using a-ITO as the material through a patterning process and an annealing process, however, embodiments of the present disclosure are not limited thereto, the conductive protection layer can be formed by using other materials.

It should be explained that, in the embodiment of the present disclosure, the a-ITO layer is processed by using an annealing process to obtain the conductive protection layer 013; through the annealing process, the a-ITO is converted into p-ITO which is impossible to be etched by methods other than an etching process using aqua regia; in this way, the first passivation metallic protection layer 012 can be prevented from being etched to expose the drain electrode when forming a via hole in the passivation layer later, so as to avoid a direct contact between the drain electrode and the pixel electrode due to exposing the drain electrode.

Step S605, forming a passivation layer on the substrate on which the conductive protection layer has been formed.

Referring to FIG. 17, which illustrates a structure with a passivation layer 015 formed on a substrate 010 on which a conductive protection layer 013 has been formed, as provided by the embodiment as illustrated in FIG. 6. FIG. 17 describes the case where the conductive protection layer 013 is the one illustrated in FIG. 14 by way of example.

The passivation layer 015 can be formed on the substrate 010 on which the conductive protection layer 013 has been formed by using a process of coating, magnetron sputtering, thermal evaporation, or plasma enhanced chemical vapor deposition (PECVD). For example, depositing a silicide with a certain thickness as the passivation layer 015 on the substrate 010 on which the conductive protection layer 013 has been formed.

Material of forming the passivation layer 015 can be selected from a group consisting of oxide, nitride and oxynitride, and corresponding reactant gas can be a mixed gas of SiR₄, NH₃ and N₂ or a mixed gas of SiH₂Cl₂, NH₃ and N₂.

Step S606, forming a via hole in the passivation layer.

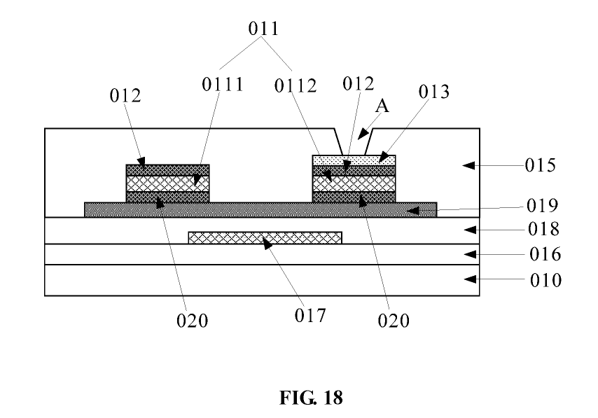

Referring to FIG. 18, which illustrates a structure with a via hole A in a passivation layer 015, as provided by the embodiment as illustrated in FIG. 6, it describes the case where the conductive protection layer 013 is the one illustrated in FIG. 14. As illustrated in FIG. 18, the via hole A is located in an area in the passvation layer 015 corresponding to the conductive protection layer 013.

The via hole A can be formed by using a patterning process. For example, forming of the via hole A in the passivation layer 015 by using a patterning process can include: coating a layer of photoresist on the passivation layer 015; exposing the photoresist by using a mask to form a fully-exposed area and a non-exposed area of the photoresist; then performing a developing process to completely remove the photoresist in the fully-exposed area and fully remain the photoresist in the non-exposed area; etching an area on the passivation layer 015 corresponding to the fully-exposed area by using an etching process so as to form the via hole A in the passivation layer 015; and then peeling off the resist in the non-exposed area. As shown in FIG. 18, after forming the via hole A, an area on the conductive protection layer 013 corresponding to the via hole A is exposed. It should be explained that, since the p-ITO can be etched off by aqua regia, the area on the passivation layer 015 corresponding to the fully-exposed area can be etched by using an etching process without aqua regia.

Step S607, forming a pixel electrode on the substrate on which the passivation layer has been formed so that the pixel electrode is contacted with the conductive protection layer through the via hole.

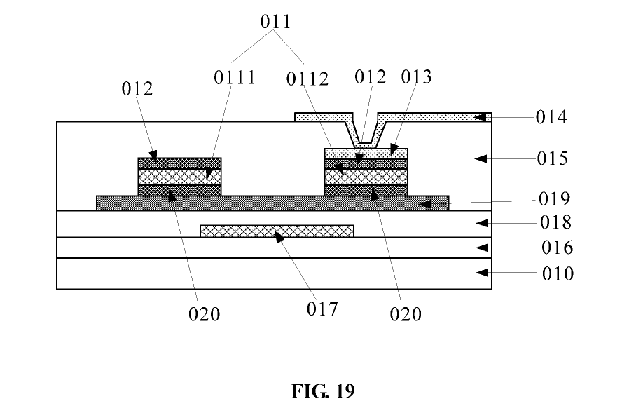

Referring to FIG. 19, which illustrates a structure with a pixel electrode 014 on a substrate 010 on which a passivation layer 015 has been formed, as provided by the embodiment as illustrated in FIG. 6. The pixel electrode 014 can be formed by using a metallic material, for example, the metallic material can be ITO, and the ITO can be a-ITO.

For example, depositing an a-ITO layer with a certain thickness on the substrate 010 on which the first passivation metallic protection layer 012 has been formed by using a-ITO as the material through a process of coating, magnetron sputtering, thermal evaporation, or plasma enhanced chemical vapor deposition (PECVD), and then processing the a-ITO layer by using a patterning process so as to obtain the pixel electrode 014. For example, processing the a-ITO layer by using the patterning process so as to obtain the pixel electrode 014 can include: coating a layer of photoresist with a certain thickness on the a-ITO layer; exposing the photoresist by using a mask to form a fully-exposed area and a non-exposed area of the photoresist; then performing a developing process to completely remove the photoresist in the fully-exposed area and fully remain the photoresist in the non-exposed area; etching an area on the a-ITO layer corresponding to the fully-exposed area by using an etching process; and then peeling off the photoresist in the non-exposed area to form the pixel electrode 014. As shown in FIG. 19, the pixel electrode 014 is contacted with the conductive protection layer 013 through the via hole in the passivation layer 015.

In the manufacturing method of an array substrate provided by the present embodiments, a conductive protection layer is formed on a first passivation protection layer to prevent the first passivation protection layer from being etched off, and hence to avoid a direct contact between a pixel electrode and a drain electrode; in this way, the problem of a relatively large resistance between the pixel electrode and the drain electrode is solved.

Embodiments of the present disclosure provide a display panel including an array substrate as illustrated in any of FIGS. 2-4.

The display panel provided by the embodiments of the present disclosure includes an array substrate, on the array substrate, a conductive protection layer is formed on a first passivation metallic protection layer to prevent the first passivation protection layer from being etched off, and hence to avoid a direct contact between a pixel electrode and a drain electrode; in this way, the problem of a relatively large resistance between the pixel electrode and the drain electrode is solved.

Embodiments of the present disclosure provide a display device including an array substrate as illustrated in any of FIGS. 2-4. The display device can be digital paper, organic light-emitting diode (OLED) display panel, mobile phone, tablet computer, television, display, notebook computer, digital photo frame, navigator and any products or components having display function.

Embodiments of the present disclosure provide a display device including an array substrate, on the array substrate, a conductive protection layer is formed on a first passivation metallic protection layer to prevent the first passivation protection layer from being etched off, and hence to avoid a direct contact between a pixel electrode and a drain electrode; in this way, the problem of a relatively large resistance between the pixel electrode and the drain electrode is solved.

An ordinary skill in the art should be appreciated that all or part of steps in the foregoing embodiments can be performed by hardware or by program instructions which can instruct relevant hardware, the program can be stored in a computer-readable storage media which can be read-only storage, magnetic disk or optic disk.

It is understood that the described above are just exemplary embodiments to explain the principle of the present disclosure and the disclosure is not intended to be limited thereto. An ordinary person in the art can make various variations and modifications to the present disclosure without departure from the spirit and the scope of the present disclosure, and such variations and modifications shall fall in the scope of the present disclosure.

The present application claims the priority and benefits of Chinese patent application No. 201510679279.5 filed on Oct. 19, 2015 and entitled “An Array Substrate and A Manufacturing Method Thereof, A Display Panel, and A Display Device”, which is incorporated herein by reference entirely.

What is claimed is:

1. An array substrate, comprising:
a substrate;
a source-drain metallic layer and a first passivation metallic protection layer formed in sequence on the substrate, the source-drain metallic layer comprising a source electrode and a drain electrode not contacted with each other;
a conductive protection layer formed on the substrate on which the first passivation metallic protection layer has been formed; and
a pixel electrode formed on the substrate on which the conductive protection layer has been formed, the pixel electrode being contacted with the conductive protection layer.

2. The array substrate according to claim 1, wherein the conductive protection layer is obtained by performing an annealing process at a temperature of 250˜270° C.

3. The array substrate according to claim 1, wherein the conductive protection layer is a polycrystalline silicon-indium tin oxide (p-ITO) protection layer.

4. The array substrate according to claim 1, further comprising a passivation layer formed on the substrate on which the conductive protection layer has been formed, a via hole is formed in the passivation layer, and the pixel electrode is contacted with the conductive protection layer through the via hole.

5. The array substrate according to claim 4, further comprising a common electrode, a gate electrode, a gate insulating layer and an active layer formed in sequence on the substrate, wherein the source-drain metallic layer and the first passivation metallic protection layer are formed on the active layer.

6. The array substrate according to claim 5, further comprising a second passivation metallic protection layer formed on the substrate on which the active layer has been formed.

7. The array substrate according to claim 6, wherein both of the first passivation metallic protection layer and the second passivation metallic protection layer are made of molybdenum.

8. A manufacturing method of an array substrate, wherein the array substrate comprises a substrate, the manufacturing method comprises:
forming a source-drain metallic layer and a first passivation metallic protection layer in sequence on the substrate, the source-drain metallic layer comprising a source electrode and a drain electrode not contacted with each other;
forming a conductive protection layer on the substrate on which the first passivation metallic protection layer has been formed; and
forming a pixel electrode on the substrate on which the conductive protection layer has been formed, the pixel electrode being contacted with the conductive protection layer.

9. The manufacturing method of an array substrate according to claim 8, wherein the conductive protection layer is a polycrystalline silicon-indium tin oxide (p-ITO) protection layer,
the method further comprising:
forming an amorphous silicon-indium tin oxide (a-ITO) layer on the substrate on which the first passivation metallic protection layer has been formed; and
performing a patterning process and an annealing process in sequence on the a-ITO layer to obtain the conductive protection layer.

10. The manufacturing method of an array substrate according to claim 8, further comprising:
performing an annealing process to the a-ITO layer at a temperature of 250˜270° C.

11. The manufacturing method of an array substrate according to claim 10, further comprising:
after forming the conductive protection layer on the substrate on which the first passivation metallic protection layer has been formed, forming a passivation layer on the substrate on which the conductive protection layer has been formed;
forming a via hole in the passivation layer; and
forming the pixel electrode on the substrate on which the passivation layer has been formed so that the pixel electrode being contacted with the conductive protection layer through the via hole.

12. The manufacturing method of an array substrate according to claim 11, further comprising: before forming a source-drain metallic layer and a first passivation metallic protection layer in sequence on the substrate,
forming a common electrode, a gate electrode, a gate insulating layer and an active layer in sequence on the substrate; and
then forming the source-drain metallic layer and the first passivation metallic protection layer in sequence on the substrate on which the active layer has been formed.

13. The manufacturing method of an array substrate according to claim 12, further comprising:
forming a second passivation metallic protection layer on the substrate on which the active layer has been formed; and
forming the source-drain metallic layer and the first passivation metallic protection layer in sequence on the substrate on which the second passivation metallic protection layer has been formed.

14. The manufacturing method of an array substrate according to claim 13, wherein,
both of the first passivation metallic protection layer and the second passivation metallic protection layer are made of molybdenum.

15. A display panel, comprising the array substrate according to claim 1.

16. A display device, comprising the array substrate according to claim 1.

17. The manufacturing method of an array substrate according to claim 8, further comprising:
after forming the conductive protection layer on the substrate on which the first passivation metallic protection layer has been formed, forming a passivation layer on the substrate on which the conductive protection layer has been formed;
forming a via hole in the passivation layer; and
forming the pixel electrode on the substrate on which the passivation layer has been formed so that the pixel electrode being contacted with the conductive protection layer through the via hole.

18. The manufacturing method of an array substrate according to claim 17, further comprising: before forming a source-drain metallic layer and a first passivation metallic protection layer on the substrate in sequence,
forming a common electrode, a gate electrode, a gate insulating layer and an active layer in sequence on the substrate; and
forming the source-drain metallic layer and the first passivation metallic protection layer in sequence on the substrate on which the active layer has been formed.

19. The array substrate according to claim 3, further comprising a passivation layer formed on the substrate on which the conductive protection layer has been formed, a via hole being formed in the passivation layer, and the pixel electrode being contacted with the conductive protection layer through the via hole.
